(19) United States
(12) Patent Application Publication
(10) Pub. No.: US 2026/0020500 A1
(43) Pub. Date: Jan. 15, 2026

(54) SYSTEMS AND METHODS FOR PHYSICAL VAPOR DEPOSITION OF SUPERCONDUCTORS

(71) Applicant: Tokyo Electron Limited, Tokyo (JP)

(72) Inventors: Hunter Frost, Albany, NY (US); Kenichi Imakita, Albany, NY (US)

(21) Appl. No.: 18/767,675

(22) Filed: Jul. 9, 2024

(51) Int. Cl. H10N 60/01; C23C 14/00; C23C 14/06; H01J 37/34; H10N 60/83; H10N 60/85

(52) U.S. Cl. CPC H10N 60/0912; C23C 14/0042; C23C 14/0641; H01J 37/3426; H10N 60/83; H10N 60/85; H01J 2237/2001; H01J 2237/332

(57) ABSTRACT

A method of forming a superconducting device includes depositing a superconducting metal nitride layer over a substrate in a plasma processing chamber charged with a first inert gas including nitrogen gas and a different second inert gas. The depositing includes sputtering metal from a metal target using the second inert gas, the sputtered metal being provided to the substrate along with a portion of the nitrogen gas.

### TECHNICAL FIELD

The present invention relates generally to the field of electronic devices, and, in particular embodiments, to methods for manufacturing electronic devices with superconducting components.

### BACKGROUND

Superconducting materials have been known for over a century, since the 1911 discovery by Kamerlingh Onnes that mercury cooled with liquid helium exhibited negligible electrical resistance. The principal phenomena associated with superconductivity are vanishing resistance and expulsion of magnetic fields from the bulk of a material, with these effects occurring below a critical temperature T_{c} and below a critical magnetic field strength H_{c}. (Critical temperatures are often well below the temperature of liquid nitrogen, 77.1 K.) Although the first superconductors identified were elemental metals, many superconducting compounds have also been discovered, with T_{c} varying among any superconducting phases according to their compositions and structures.

Electronic devices incorporating superconductors, including superconducting compounds, are increasingly being used for applications in areas such as quantum computing, sensing, and metrology. Some such devices rely on the properties of the superconducting material when held below T_{c}, while others depend for their function on the switching of properties that occurs when the temperature moves through T_{c} or when the magnetic field moves through H_{c}. Irrespective of the details, the superconducting material will eventually be integrated with other materials and with wiring to form a complete and connected device, which will be cryogenically cooled when in operation.

### SUMMARY

A method of forming a superconducting device includes depositing a superconducting metal nitride layer over a substrate in a plasma processing chamber charged with a first inert gas including nitrogen gas and a different second inert gas. The depositing includes sputtering metal from a metal target using the second inert gas, the sputtered metal being provided to the substrate along with a portion of the nitrogen gas.

A method includes forming a Josephson junction including a first superconducting metal nitride layer, a second superconducting metal nitride layer, and a tunnel barrier disposed between the first superconducting metal nitride layer and the second superconducting metal nitride layer, the first superconducting metal nitride layer and the second superconducting metal nitride layer being formed by sputtering metal from a metal target using krypton in a plasma processing chamber charged with nitrogen gas.

A method includes forming a waveguide over a substrate; forming a superconducting metal nitride layer over the waveguide, the superconducting metal nitride layer being formed by sputtering metal from a metal target using krypton in a plasma processing chamber charged with nitrogen gas; patterning the superconducting metal nitride layer to form a superconducting nanowire; and forming metal contacts connected at each end of the superconducting nanowire.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A and 1B illustrate cross-sectional schematic views of physical vapor deposition (PVD) apparatus for sputtering metal from a metal target onto a substrate along with a process gas, in accordance with embodiments of the invention, wherein FIG. 1A illustrates a capacitively coupled plasma apparatus and FIG. 1B illustrates an inductively coupled plasma apparatus;

FIGS. 2A and 2B illustrate cross-sectional views of the electrodes and process gases in the plasma processing chamber before and after ignition of the plasma, in accordance with embodiments of the invention;

FIG. 3 provides a partial temperature-composition phase diagram for niobium nitride, with several homogeneous phases and mixtures indicated, as used in embodiments of the invention;

FIG. 4 is a plot of the composition of niobium nitride films formed by PVD in an argon plasma as a function of nitrogen pressure;

FIG. 5 is a plot of the composition of niobium nitride films formed by PVD in an argon plasma as a function of process pressure and the percent pressure of nitrogen;

FIG. 6 is a plot comparing the compositions of niobium nitride films formed by PVD in argon and krypton plasmas as a function of process pressure and the percent pressure of nitrogen, according to an embodiment;

FIG. 7 is a table showing the single-o variation in thickness of niobium nitride films formed by PVD in argon plasma as a function of process pressure for nearly constant percent pressures of nitrogen, in accordance with embodiments;

FIGS. 8A-8C illustrate cross-sectional views of the formation by a planar process of a superconductor-on-metal-on-substrate structure, according to various embodiments;

FIGS. 9A-9I illustrate cross-sectional views of the formation by a planar process of a Josephson junction (superconducting tunnel junction), according to various embodiments;

FIGS. 10A-10I illustrate corresponding top-down views of the formation by a planar process of a Josephson junction (superconducting tunnel junction), according to various embodiments;

FIG. 11 provides a circuit diagram for a transmon qubit incorporating an embodiment Josephson junction, the transmon being coupled to a readout resonator addressable with a microwave oscillator, according to an embodiment;

FIG. 12 provides a circuit diagram for a fluxonium qubit incorporating an embodiment Josephson junction, the fluxonium qubit being coupled to a readout resonator addressable with a microwave oscillator, according to an embodiment;

FIGS. 13A-13G illustrate cross-sectional views of the formation by a planar process of a superconducting nanowire single-photon detector, according to various embodiments;

FIGS. 14A-14G illustrate corresponding top-down views of the formation by a planar process of a superconducting nanowire single-photon detector, according to various embodiments;

FIG. 15 provides an equivalent circuit diagram for an embodiment superconducting nanowire single-photon detector, according to an embodiment;

FIG. 16 is a flowchart for a method of depositing a superconducting metal nitride layer over a substrate in accordance with embodiments;

FIG. 17 is a flowchart for a method, and in particular a method for forming a Josephson junction in accordance with embodiments; and

FIG. 18 is a flowchart for a method, and in particular a method for forming a superconducting nanowire over a waveguide in accordance with embodiments.

### DETAILED DESCRIPTION OF ILLUSTRATIVE EMBODIMENTS

Embodiments of the present invention enable deposition of metal nitrides in superconducting phases under room temperature conditions. Room-temperature PVD allows for integration of superconductors with structures formed from materials that may be blurred (or even destroyed) by the elevated temperatures required for evaporation or other processes. Moreover, the ability to fabricate integrated superconducting structures and devices using planar processes may greatly simplify process flows.

Room-temperature deposition also enables the production and integration of semiconductors with better properties. A pure sample of any given superconductor will have a certain T_{c}, and as impurities are introduced, T_{c} will generally be lowered. Room-temperature deposition allows production of higher-T_{c} phases of a superconductor for integration with other materials while simultaneously limiting permeation and subsequent diffusion of those materials into the superconductor. The properties of an integrated superconductor produced by this method, such as its electrical resistance and kinetic inductance, may be closer to that of the pure phase. The present invention, in various embodiments, therefore enables the production of better-performing devices while also providing a practical benefit by way of more consistent (and less stringent) requirements for cooling.

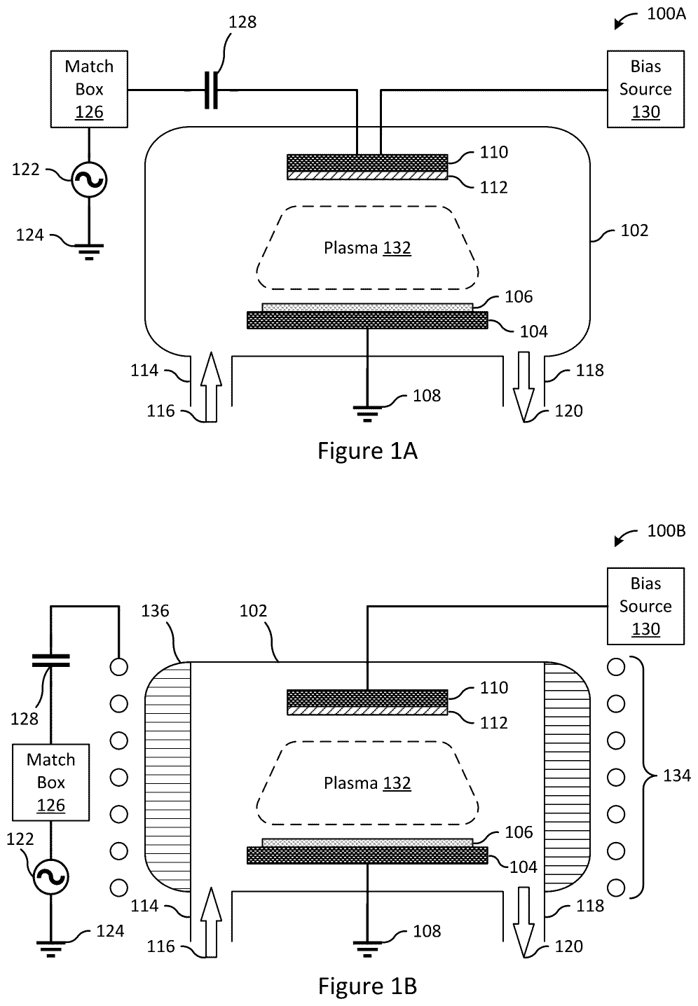

Because embodiments of the present invention relate to the methods by which this sputtering and deposition is performed, we now describe the PVD process in detail, with reference to FIG. 1A.

FIG. 1A depicts a cross-sectional schematic view of a capacitively coupled PVD apparatus 100A that may be used to form a superconducting film. A plasma processing chamber 102 is configured to contain two electrodes. We will refer to these electrodes as a lower electrode 104 and an upper electrode 110, consistent with the placement of the electrodes in FIG. 1A, but different embodiments of the present invention may use different configurations of these components to achieve the same ends. For example, some embodiments may instead use a peripheral electrode.

In FIG. 1A, the lower electrode 104 is configured to hold or support a substrate 106. Substrate 106 represents generically any suitable semiconductor workpiece being processed in accordance with embodiments of the present invention. The substrate 106 may be a bulk substrate such as a blank silicon wafer, a silicon-on-insulator (SOI) wafer, or any of various other semiconductor substrates. The substrate 106 may also be coated, or layered with any number of additional materials, including compound semiconductors, metal or metalloid oxides, or metal or metalloid nitrides. The substrate 106 may include any material portion or structure of a device, particularly a semiconductor or other electronics device. Similarly, in some embodiments, the substrate 106 may itself be patterned or embedded in other components of a semiconductor structure or device.

In some embodiments, the lower electrode 104 may further incorporate heating or cooling elements, temperature controls, vacuum suction, or other means of securing and controlling the physical state of the substrate 106. In some embodiments, and as illustrated, the lower electrode 104 may be connected to a ground 108, such that any voltage difference between the lower electrode 104 and the upper electrode 110 may arise from voltages applied to the upper electrode 110. In other embodiments, a separately controllable voltage may be applied to lower electrode 104.

The upper electrode 110 is configured to hold or support a metal target 112. Metal target 112 represents generically any suitable metal ingot, foil, or other bulk sample. In some embodiments, metal target 112 may comprise a single crystal of a chosen phase of a metal, while in other embodiments metal target 112 may be a polycrystalline sample.

In some embodiments, the upper electrode 110 may further incorporate heating or cooling elements, temperature controls, vacuum suction, or other means of securing and controlling the physical state of the metal target 112. In some such embodiments, the upper electrode 110 may be augmented with permanent magnets in order to perform magnetron sputtering.

The plasma processing chamber 102 is configured with a gas inlet 114 to permit charging of the plasma processing chamber 102 with process gases. The gas inlet 114 may be connected to one or more gas lines, canisters, or bottles configured to supply process gas, as indicated by an in-flow 116, as well as valves or other control mechanisms to turn on, turn off, or otherwise regulate gas flow. A gas outlet 118 may be connected to one or more pumps, as well as valves or other control mechanisms to turn on, turn off, or regulate the pumping, as indicated by an out-flow 120. Pumping and the associated out-flow 120 may be used to evacuate the plasma processing chamber 102 before beginning PVD or to ensure stable maintenance of a chosen process pressure when the in-flow 116 is ongoing.

In some embodiments, and as illustrated in FIG. 1A, the upper electrode 110 may be coupled to an RF power supply 122; the RF power supply 122 may itself be connected at one end to ground 124. The RF power supply 122 may be coupled to the upper electrode 110 by way of impedance-matching circuitry (such as a match box 126) and a blocking capacitor 128 that blocks any DC voltage that may build up on the upper electrode 110 from the RF power supply 122. According to various embodiments, the RF power supply 122 may operate at high frequency, at very high frequency, or in an even higher frequency regime.

In some embodiments, additional biases may also be applied to the upper electrode 110 from a bias source 130. In certain of these embodiments, the bias source 130 may include an additional AC power supply and additional impedance-matching circuitry; in other such embodiments, the bias source 130 may include a DC power supply and an RF choke. In other embodiments, the RF power supply 122 and the bias source 130 may both be coupled to the lower electrode 104, or they may be coupled to opposing electrodes.

The resulting voltage difference between the upper electrode 110 and the lower electrode 104 may be negative, such that the upper electrode 110 may carry an excess of electrons and thus also be referred to as a cathode. In other embodiments, any power supplies and bias sources may be configured such that the cathode may be whichever electrode supports or holds the metal target 112.

For purposes of PVD, pumps connected to the gas outlet 118 may produce a sufficient out-flow 120 to pump the plasma processing chamber 102 down to a pressure consistent with high vacuum, between 10⁻⁵ torr and 10⁻⁸ torr. The out-flow 120 may then be reduced and process gases may be introduced into the plasma processing chamber 102 through the gas inlet 114 such that the balance between the in-flow 116 and the out-flow 120 establishes a desired process pressure. In some embodiments, the process pressure may be between 0.5 and 1.0 mtorr; in other embodiments, the process pressure may be as low as 0.25 mtorr or as high as 30 mtorr. Note, however, that it may be difficult (or impossible) to ignite and sustain a plasma 132 in the plasma processing chamber 102 if the process pressure is too low.

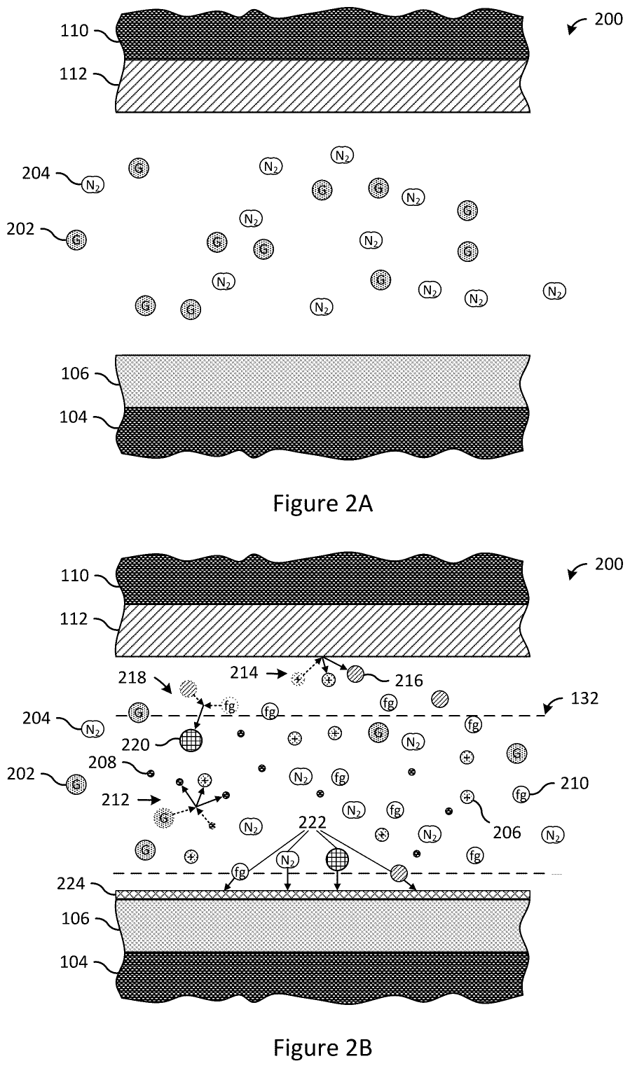

FIG. 2A presents a schematic view of the interior of the plasma processing chamber 102, and more specifically, a microscopic volume between the upper electrode 110 and the lower electrode 104. (Note that the distance between the electrodes is not drawn to scale.) After introduction of process gases into the plasma processing chamber 102, this microscopic volume may include a carrier gas 202. In conventional PVD processes, the carrier gas 202 may be argon; in embodiments of the present invention, the carrier gas 202 may instead be krypton, xenon, or a mixture of these gases (with or without argon). Additional gases may also be present in this volume in order to carry out reactive sputtering; for example, in embodiments of the present invention, and as illustrated in FIG. 2A, nitrogen gas 204 may be introduced into the plasma processing chamber 102 as a source of nitrogen atoms for forming superconducting nitride compounds.

When the voltage in the plasma processing chamber 102 is sufficiently high, a small fraction of the atoms of the carrier gas 202 may be ionized, producing (with reference to FIG. 2B) carrier gas cations 206 and electrons 208. The necessary voltage may vary as a function of the distance between the electrodes, subject to e.g., Paschen's law for breakdown voltages. (In some embodiments, the applied voltage and the interelectrode distance may respectively be between −50V and −5 kV and between 5 cm and 50 cm.) The energy delivered to the carrier gas 202 in any case is higher than the first ionization energy (IE) of the constituent atoms. Argon has a first IE of 15.8 eV. In embodiments of the present invention, the carrier gas 202 may be krypton, with first IE of 14.0 eV, or xenon, with first IE of 12.1 eV, or it may be a mixture of these noble gases (with or without argon). In such embodiments, the voltages applied to achieve initial ionization of the carrier gas 202 may be lower than when argon is used.

Once a sufficient fraction of the atoms of the carrier gas 202 has been ionized—typically between 1 ppb and 1 ppm—avalanche ionization processes 212 may occur, in which one of the electrons 208 generated by the initial ionization may collide with an atom of the carrier gas 202 to produce a new carrier gas cation 206 and an additional electron 208. In this way, the ionization becomes self-sustaining, and a plasma 132 is ignited. (According to an embodiment, the fraction of atoms of the carrier gas 202 ionized may be between 10 ppm and 1 part per thousand. With reference to FIG. 1A, in accordance with some embodiments, the plasma 132 may be shaped by choosing the upper electrode 110 to be smaller than the lower electrode 104, such that plasma sheath voltages may be enhanced near the upper electrode 110 and tend to draw carrier gas cations 206 more strongly toward the metal target 112. In other embodiments, the upper electrode 110 and the lower electrode 104 may be the same size.

With further reference to FIG. 2B, a variety of other microscopic processes may take place within the plasma processing chamber. In particular, a sputtering 214 may occur, in which one of the carrier gas cations 206 is attracted toward the negatively charged upper electrode and undergoes a collision with the metal target 112, causing ejection of one or more metal particles 216. A metal particle 216 may comprise one or more atoms of the metal target 112 and may be ionized or neutral depending on the detailed mechanism of each sputtering 214.

Because the nitrogen molecule has a first IE lower than that of argon and comparable to that of krypton, some fraction of the nitrogen gas 204 may also be ionized to produce nitrogen molecular cations and electrons 208. (For purposes of illustration, all nitrogen-containing ions, molecular fragments, and neutral atoms are represented as fragment particles 210.) Various reactive collisions 218 between metal particles 216 and fragment particles 210 may then occur, producing in some cases a metal nitride particle 220. While it is also possible that fragment particles 210 with positive charge may be drawn towards and collide with the surface of the metal target 112, the result may either be additional sputtering of metal particles 216 or (perhaps) temporary nitridation of the metal target 112 that will be sputtered away by subsequent collisions.

The deposition of a metal nitride layer 224 over the substrate 106 may then occur through a variety of deposition processes 222. For example, nitrogen gas 204, fragment particles 210, metal particles 216, or metal nitride particles 220 may adsorb onto the substrate 106 and then bond laterally to form the metal nitride layer 224. (Incorporation of carrier gas 202 into the metal nitride layer 224 may be minimal, on the order of ppm.) Once some portion of the metal nitride layer 224 has formed, further deposition processes 222 may occur over that portion and thicken the metal nitride layer 224.

The composition and phase of the metal nitride layer 224 may vary according to the particular choice of carrier gas 202, process pressure, percent pressure of nitrogen gas 204 in the plasma processing chamber 102, and the process temperature. In some embodiments, the process temperature may be between 15° C. and 30° C. In other embodiments, the temperature may be somewhat higher, between 30° C. and 100° C. In still other embodiments, the process temperature may be between 100° C. and 300° C. Process pressures will be addressed further below.

The description provided thus far applies to a capacitively coupled PVD apparatus 100A; in some embodiments, and with reference to FIG. 1B, an inductively coupled PVD apparatus 100B may be used instead. Using like reference numerals for like components, the principal difference between capacitively coupled PVD apparatus 100A and inductively coupled PVD apparatus 100B is that the circuit elements associated with the RF power (i.e., the RF power supply 122, the ground 124, the match box 126, and the blocking capacitor 128) may be connected to an inductive coil 134. In an embodiment, the inductive coil 134 may wind around the plasma processing chamber 102, while in another embodiment, the inductive coil 134 may be disposed over a window on top of the chamber. (The small circles in FIG. 1B represent cross-sections of the inductive coil 134 as it passes through the sectioning plane.) Dielectric windows 136 may permit the field generated by the inductive coil 134 to penetrate into the interior of the plasma processing chamber 102 and thereby to ignite the plasma 132. The bias source 130 may still be connected to the upper electrode 110, in some embodiments. In other embodiments, the bias source may be connected elsewhere, such as to the lower electrode 104 or to a peripheral electrode.

Embodiments of the present invention may be used to deposit a variety of superconducting materials, enabling their fabrication and integration with other materials to form electronic devices. These superconducting materials may, in some embodiments, be elemental metals, including transition metals such as niobium or tantalum or main-group metals such as aluminum or titanium. In other embodiments, the superconducting materials may be metal alloys, such as near-stoichiometric niobium-titanium alloy (NbTi). In still other embodiments, the superconducting materials may be nitrides of one or more transition metals or main-group metals, such as TiN, NbN, TaN, or NbTiN, with the formulas in an embodiment being intended merely to indicate the constituent elements rather than a precise stoichiometry.

Superconducting metal nitrides are generally more resistant to oxidation than the base metals. Indeed, in multi-metal nitrides, one metal may function as an “oxygen getter,” undergoing sacrificial oxidation in order to preserve electron density on the other metal, which is the main driver of the superconductivity. NbTiN is one such nitride, with titanium protecting niobium from oxidation. Irrespective of the mechanism, such resistance is advantageous: Oxidation may degrade device performance significantly, especially in quantum computing devices that may malfunction when environmental interactions decohere a superposed qubit during a calculation.

Superconducting metal nitrides may have other salutary properties, including a higher kinetic inductance than the corresponding elemental metals, owing to the relative reduction in density of charge carriers when nitrogen is incorporated. As a result, superconducting metal nitrides may be preferred for certain metrological applications, such as kinetic inductance detectors or superconducting nanowire single-photon detectors (SNSPDs).

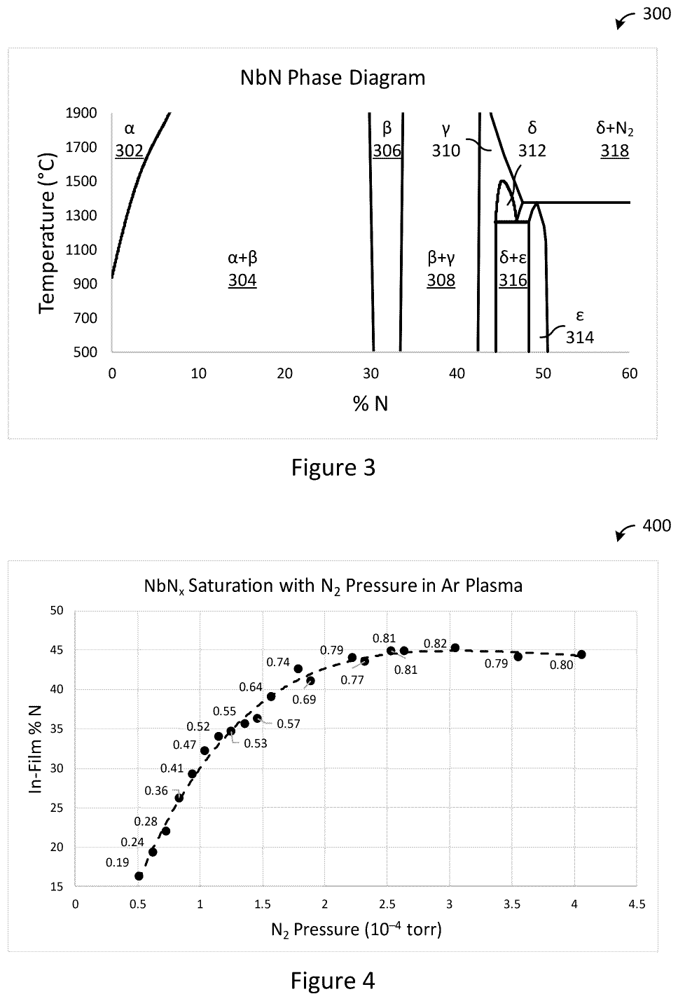

One such metal nitride, niobium nitride (NbN), provides a concrete example of the advantages of the present invention in various embodiments. NbN is conductive under normal conditions, such that it may be used to form electrodes and contacts. It was discovered to be superconductive under cryogenic conditions as early as 1941, and it has a complex temperature-composition phase diagram 300 (with reference to FIG. 3). Note that the phase diagram 300 is a high-temperature phase diagram beginning at 500° C.; the inventors have observed that the phases obtained by room-temperature PVD correspond to those otherwise produced at temperatures between 1000° C. and 1500° C.

The composition of NbN in phase diagram 300 may be characterized by a percentage of nitrogen, with 0% corresponding to pure niobium and 50% corresponding to stoichiometric NbN (i.e., both elements having an implied subscript of 1). Other compositions with n % nitrogen correspond either to a homogeneous NbNₓ phase with x=n/(100−n) or to a heterogeneous mixture of two or more phases, including (in some cases) gaseous nitrogen.

Elemental niobium has the highest T_{c} of the transition metals, and the various phases of NbN are known to be superconducting, with T_{c} between 9.2 K (corresponding to pure niobium) and 17.3 K (corresponding to nearly stoichiometric, cubic (rock salt)-structured δ-NbN 312). The latter T_{c} is the highest known among superconducting transition-metal nitrides.

Other NbN phases include (but are not limited to) α-NbN 302, effectively a solid solution of nitrogen atoms in body-centered cubic niobium, Nb (N); β-NbN 306, with a hexagonal (tungsten semicarbide) structure and approximate Nb₂N stoichiometry; γ-NbN 310, with a tetragonal (distorted sodium chloride) structure and approximate Nb₄N₃ stoichiometry; and nearly stoichiometric ϵ-NbN 314, with a hexagonal (anti-tungsten carbide) structure. There are also regions in the phase diagram in which grains with different structures mix, such as the α+β phase 304, β+γ phase 308, and δ+ϵ phase 316. When the nitrogen percentage exceeds 50%, such that x>1, solid phases may also coexist with gaseous nitrogen, as in the δ+N₂ region 318.

δ-NbN 312 is the preferred phase for superconducting devices based on NbN, although ϵ-NbN 314 (with Tc˜11.6 K) or δ+ϵ phase 316 (with intermediate Tc) may also be acceptable for use in some devices. In the latter case, the Holm-Meissner proximity effect partially homogenizes electronic properties (and thus superconducting behavior) across grains of different phases, effectively raising the T_{c} of ϵ-NbN 314 in contact with δ-NbN 312. Accordingly, a target percentage of nitrogen in the NbNₓ composition may be between 44% and 50%, corresponding to 0.79<x≤1.0, with higher values in this range, away from the coexistence lines with other phases, being preferred.

The inventors have observed that NbN films deposited by conventional PVD with an argon plasma barely achieve the lower values in this range, as illustrated in the pressure-in-film % N chart 400 of FIG. 4. As the nitrogen pressure is increased from 0.5 mtorr to just over 0.4 mtorr, x saturates, never reaching a value higher than 0.82.

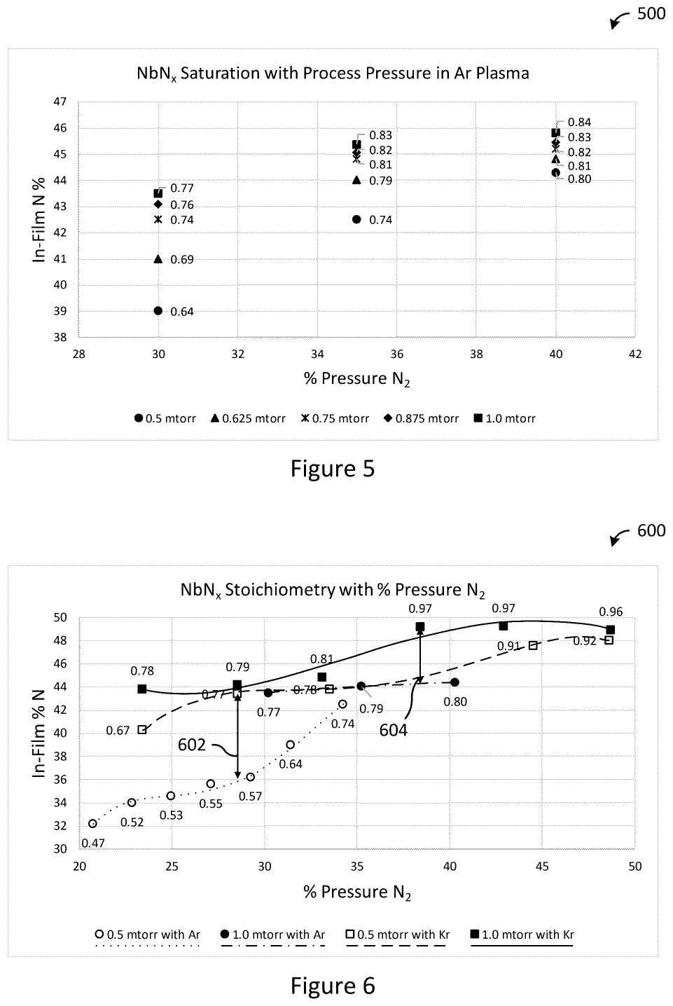

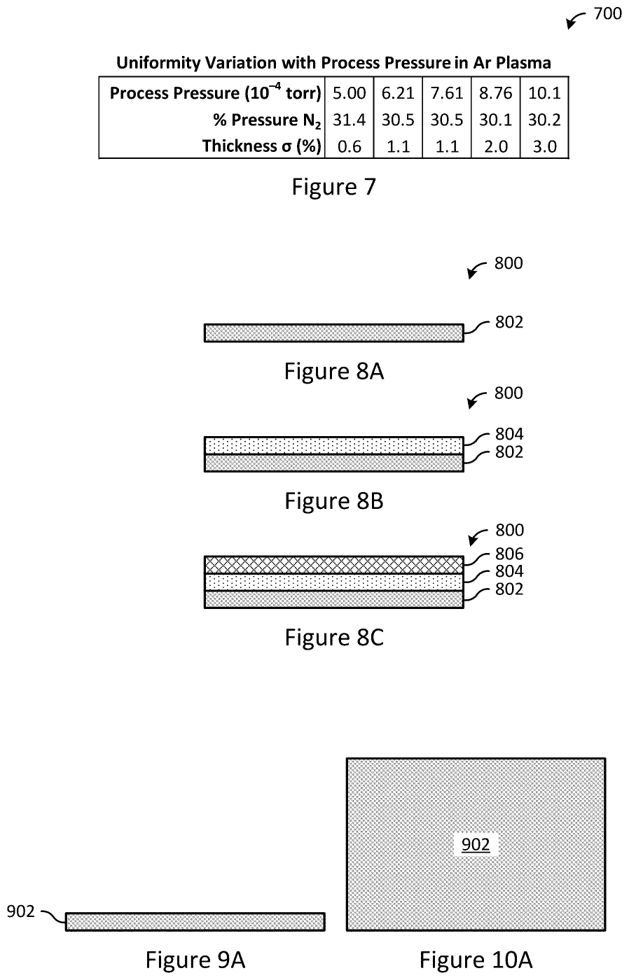

The inventors have further observed that raising process pressures by introducing additional argon carrier gas only increases the value of x at saturation by about 2.5%, to 0.84 (as illustrated in the % pressure N₂-in-film % N chart 500 of FIG. 5). Increasing the process pressure may have negative consequences, however: As provided in Table 1 700 of FIG. 7, the inventors have measured the standard deviation o in the thickness of 50 nm films deposited by conventional PVD in an argon plasma and found that it grows to as much as 3% of the average (1.5 nm) at higher process pressures, exceeding a typical 1% tolerance. Given that metal nitride films as thin as 5 nm may be fabricated for certain applications, such as SNSPDs, a 3 nm variation may be completely intolerable.

The inventors have established through experimentation that the de facto saturation limit of x˜0.84 may be exceeded-even at modest process pressures of 0.5 mtorr-by replacing the conventional argon carrier gas with krypton, in accordance with an embodiment. (See the % pressure N₂-in-film % N comparison chart 600 of FIG. 6.) Use of krypton as the carrier gas 202 may increase in-film % N by as much as 21% relative to argon at lower process pressures (as indicated by a first double-headed arrow 602) or by as much as 11% relative to argon at higher process pressures and in the saturation region (as indicated by a second double-headed arrow 604). Moreover, essentially the entire targeted range of in-film nitrogen percentages and x values may be accessed by PVD in a krypton plasma, with thickness variations in 50 nm films well within the 1% target for process pressures as high as 1.0 mtorr.

The advantages just enumerated of krypton as the heavier carrier gas 202 are counterintuitive, and their origin remains unclear. Krypton having a lower first IE than argon implies that more carrier gas cations 206 and electrons 208 may be produced given the same applied voltage, and that the resulting plasma may have a higher degree of ionization and a higher temperature (i.e., average kinetic energy per particle, distinct from the process temperature characterizing the substrate 106 and the metal target 112). Taken together, these facts imply in turn that there may be proportionally more sputtering 214 to produce metal particles 216, tending to increase the number of deposition processes 222 adding metal to the metal nitride layer 224 and to lower the in-film nitrogen percentage-exactly the opposite of the observed effect.

The enhanced deposition of nitrogen into the metal nitride layer 224 may therefore be a consequence of other phenomena. Changes in the mean free path of particles in the plasma 132—and a greater proportion of carrier gas cations 206 and electrons 208 relative to nitrogen gas 204 and fragment particles 210—may drive new fragmentation chemistry and also increase the rate of reactive processes 218 producing metal nitride particles 220. A different mix of fragment particles 210 may also be produced, or changes in the kinetic and internal energies of metal particles 216 and fragment particles 210 may allow new reactive processes 218 to produce metal nitride particles 220 relatively enriched in nitrogen. The observed enhancements may be the result of still other, wholly unanticipated phenomena. Nevertheless, they demonstrate the advantages of embodiments of the present invention using krypton as the carrier gas 202 over conventional processes using argon, namely, that superconducting phases may be deposited at room temperature and with excellent uniformity.

A further advantage of embodiments of the present invention is that it enables the integration of superconductors into device stacks incorporating a variety of materials, such as metals, sacrificial dielectrics, oxides, exposed elemental silicon, etc., some of which may be undesirably annealed diffused, distorted, or destroyed in the course of high-temperature deposition. That being the case, embodiments enable the formation of complex superconducting devices by conventional planar processes that currently require three-dimensional methods such as shadow evaporation.

In other words, embodiments of the present invention enable process flows like that illustrated in FIGS. 8A-8C. Beginning in FIG. 8A with a substrate 802, which may be a substrate in the sense described above, a superconductor-on-metal structure 800 may be formed in two steps. As depicted in FIG. 8B, a metal layer 804 may first be deposited using any suitable deposition technique, such as physical vapor deposition (PVD) by sputtering, evaporation, or molecular beam evaporation; pulsed laser deposition (PLD); atomic layer deposition (ALD); chemical vapor deposition (CVD); plasma-enhanced CVD or ALD; metal-organic CVD; low-pressure CVD; rapid thermal CVD; or any other layer deposition process or combination thereof. The metal deposited may be any desirable metal, such as a common metallization element like aluminum, nickel, copper, silver, or gold, or an alloy thereof.

In the second step, depicted in FIG. 8C, a superconducting metal nitride layer 806 may be deposited over the metal layer 804 by PVD employing a plasma comprising krypton and/or xenon, according to embodiments of the present invention. Because the second deposition step may be carried out at room temperature, the superconductor-on-metal structure 800 may be obtained without significant distortion or diffusion between layers. Moreover, the superconducting metal nitride layer 804 may comprise phases, such as δ-NbN 312 or ϵ-NbN 314, that would otherwise require deposition temperatures between 1000° C. and 1500° C., melting some or all of the metals mentioned above and preventing the formation of the superconductor-on-metal structure 800 altogether.

Embodiments of the present invention further enable the formation of a variety of electronic devices, such as those based on superconducting tunnel junctions, also referred to as Josephson junctions. Josephson junctions comprise two superconductors separated by a sufficiently thin insulating barrier that quantum mechanical tunneling may allow current to flow.

A Josephson junction may be characterized by a nonlinear inductance associated with the flowing supercurrent in parallel with a parasitic capacitance, forming an anharmonic oscillator. This oscillator's lowest two accessible energy levels-corresponding to adjacent charge states of the junction-may be adjusted using a gating capacitor and are addressable at distinct frequencies, establishing a two-level subspace that may be used as a qubit. Embodiments of the present invention may thus enable improved manufacturing processes for quantum computing architectures incorporating qubits based on Josephson junctions.

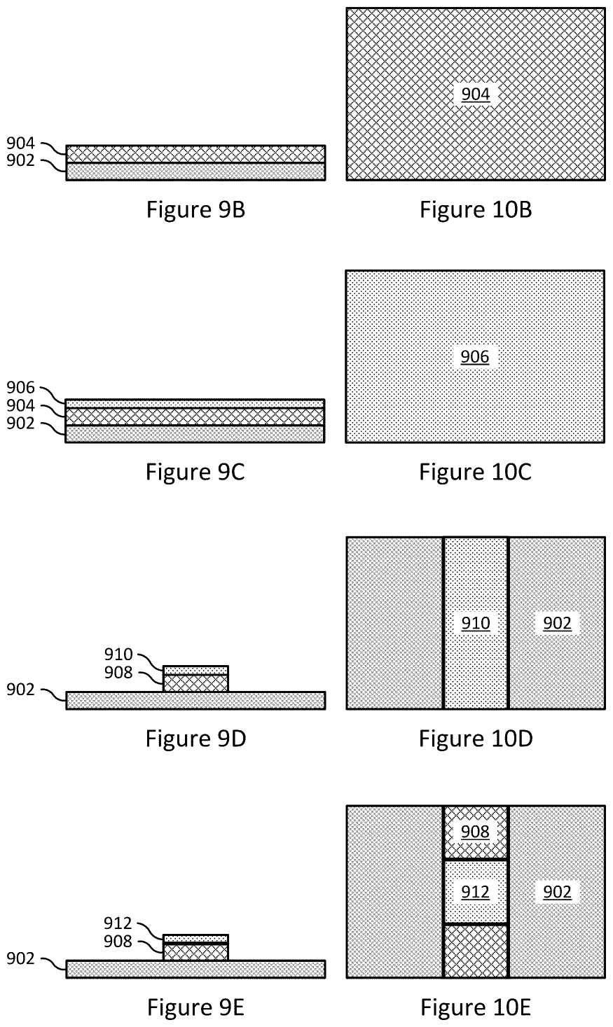

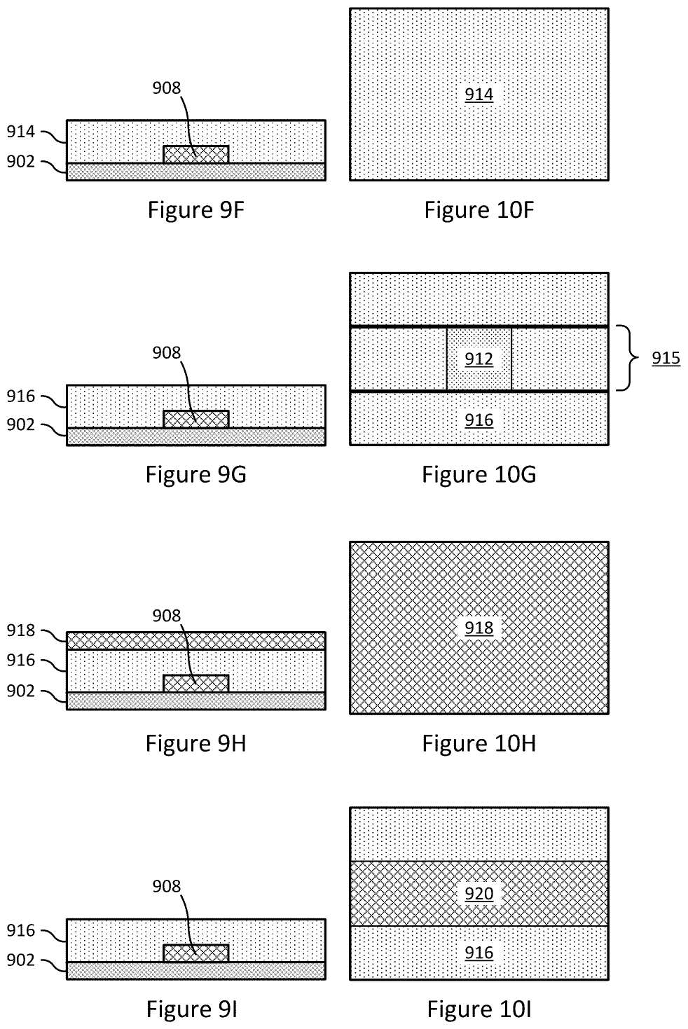

FIGS. 9A-9I and 10A-10I respectively depict cross-sectional and top-down views of the formation of a Josephson junction, in accordance with various embodiments. (Like reference numerals are used to refer to identical features of the two figures.) Beginning in FIGS. 9A and 10A with a substrate 902, which may be a substrate in the sense described above, the device may be formed as follows:

As depicted in FIGS. 9B and 10B, a first superconducting metal nitride layer 904 may be deposited over the substrate 902 by PVD employing a plasma comprising krypton and/or xenon, according to embodiments of the present invention. In some embodiments, the first superconducting metal nitride layer 904 may comprise niobium nitride in the δ-NbN 312 or ϵ-NbN 314 phase, or the δ+ϵ phase 316. In other embodiments, the first superconducting metal nitride layer 904 may comprise niobium nitride in another phase. In still other embodiments, the first superconducting metal nitride layer 904 may comprise a nitride of another transition metal or main-group metal, such as TiN, TaN, or NbTiN.

Next, as depicted in FIGS. 9C and 10C, a thin tunnel barrier 906 comprising a resistive oxide or nitride may be deposited over the first superconducting metal nitride layer 904 using any suitable deposition technique, such as PVD by sputtering, evaporation, or molecular beam evaporation; PLD; ALD or plasma-enhanced ALD; CVD, plasma-enhanced CVD, metal-organic CVD, low-pressure CVD, or rapid thermal CVD; or any other layer deposition process or combination thereof. The thin tunnel barrier 906 may comprise aluminum oxide, aluminum nitride, or tantalum nitride, according to various embodiments. In such embodiments, the thin tunnel barrier 906 may have thickness between 1 nm and 20 nm.

The thin tunnel barrier 906 and the first superconducting metal nitride layer 904 may then (with reference to FIGS. 9D and 10D) be patterned to form a linear tunnel barrier 910 disposed over a linear superconducting metal nitride electrode 908. An additional patterning step may be used to shape the linear tunnel barrier 910 into a tunnel barrier patch 912 over the linear superconducting metal nitride electrode 908, as depicted in FIGS. 9E and 10E. The critical dimension for these features may be greater than 100 nm, e.g., between 100 nm and 500 nm and therefore may be patterned using any suitable lithography technique, such as dry lithography (e.g., using 193-nanometer dry lithography), immersion lithography (e.g., using 193-nanometer immersion lithography), i-line lithography (e.g., using 365-nanometer wavelength UV radiation for exposure), H-line lithography (e.g., using 405-nanometer wavelength UV radiation for exposure), extreme UV (EUV) lithography, or deep UV (DUV) lithography.

Fourth, as depicted in FIGS. 9F and 10F, an interlayer dielectric 914 may be deposited over the tunnel barrier patch 912, the linear superconducting metal nitride electrode 908, and the substrate 902. The interlayer dielectric 914 may be deposited using any suitable deposition technique, such as PVD by sputtering, evaporation, or molecular beam evaporation; PLD; ALD or plasma-enhanced ALD; CVD, plasma-enhanced CVD, metal-organic CVD, low-pressure CVD, or rapid thermal CVD; or any other layer deposition process or combination thereof. In embodiments with the interlayer dielectric 914 comprising silicon oxide, the interlayer dielectric 914 may (for example) be deposited by metal-organic CVD using tetraethyl orthosilicate.

The remaining steps depicted in FIGS. 9 and 10 are a single damascene process that forms a perpendicular superconducting metal nitride electrode 920 (with reference to FIGS. 9I and 10I) to complete the Josephson junction. As depicted in FIGS. 9G and 10G, a trench 915 may be patterned and etched into the interlayer dielectric 914 perpendicular to the linear superconducting metal nitride layer 1908, forming a trenched interlayer dielectric 916 and exposing a top surface of the tunnel barrier patch 912. The interlayer dielectric 914 may be patterned using any suitable lithography technique, such as dry lithography, immersion lithography, i-line lithography, H-line lithography, EUV lithography, or DUV lithography. The trench 915 may then be etched using any suitable dry etching method, such as reactive ion etching.

As depicted in FIGS. 9H and 10G, the trenched interlayer dielectric 916 may then be filled with a second superconducting metal nitride layer 918. The second superconducting metal nitride layer 918 may be deposited over the substrate 902 by PVD employing a plasma comprising krypton and/or xenon, according to embodiments of the present invention. In some embodiments, the second superconducting metal nitride layer 918 may comprise the same material as the first superconducting metal nitride layer 904. In other embodiments, the second superconducting metal nitride layer 918 may comprise a different transition metal nitride or main-group metal nitride with a superconducting phase.

As depicted in FIGS. 91 and 101, the second superconducting metal nitride layer 918 may next be etched with a suitable isotropic etching method, such as reactive ion etching with an Ar/CF₄ mixture in one embodiment, or subjected to chemical mechanical planarization to form a perpendicular superconducting metal nitride electrode 920 that is flush with an exposed top surface of the trenched interlayer dielectric 916. The product of the steps illustrated in FIGS. 9A-9I and FIGS. 10A-10I is a complete Josephson junction device in crosspoint configuration. The completed Josephson junction may be further integrated to form a variety of devices and circuits, according to various embodiments.

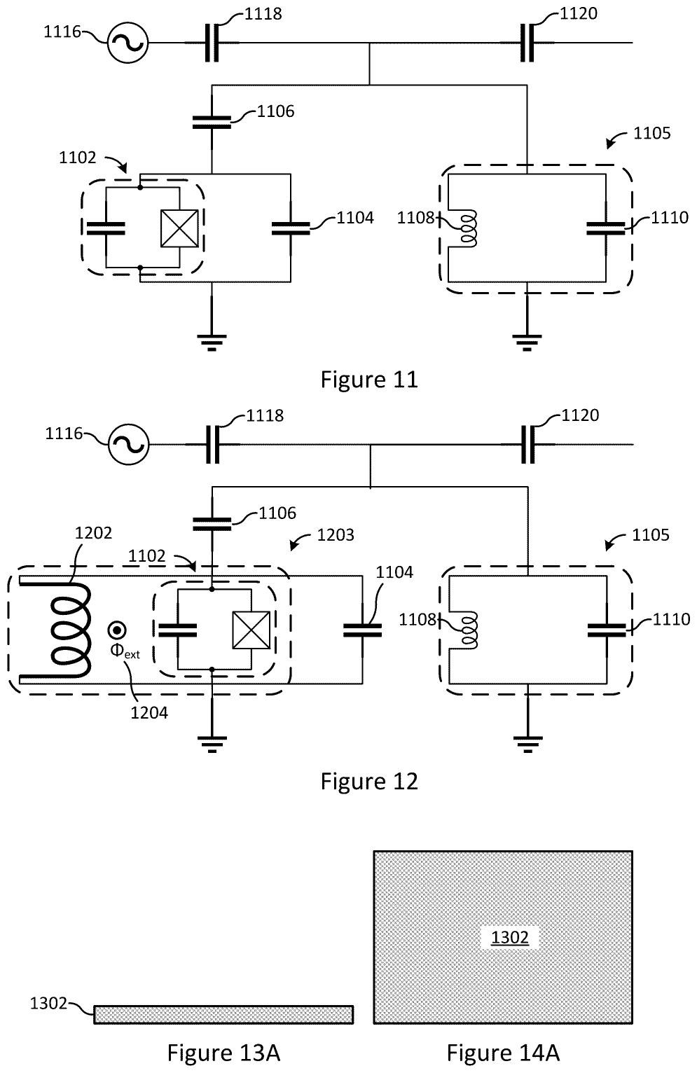

FIGS. 11 and 12 provide equivalent circuits for a small selection of devices that may incorporate an embodiment Josephson junction of the type formed by the process of FIGS. 9 and 10. (Like reference numerals are used for like components in the two figures.) A customary representation of a Josephson junction 1102 used in both figures comprises a box crossed at the diagonals (representing the junction itself, and associated with the nonlinear inductance of the junction) and connected in parallel with a capacitor (representing the parasitic capacitance of the junction).

As described above, the Josephson junction 1102 implements an anharmonic oscillator with an addressable two-level subspace. The frequencies of the two-level subspace may be tuned by gate capacitor 1106, typically within the microwave band. The Josephson junction 1102 may be coupled to a readout resonator 1105 comprising a linear inductor 1108 and a resonator capacitor 1110, the respective inductance L and capacitance C being chosen to produce a harmonic oscillator with a frequency ω=\sqrt{1/LC} also in the microwave band. Coupling to the Josephson junction 1102 may cause a dispersive shift in the frequency @ of the readout resonator 1105 that depends on the quantum mechanical state of the Josephson junction 1102. Consequently, the state may be measured by probing with a pulse from a microwave oscillator 1116 coupled to an input capacitor 1118; to the coupled Josephson junction 1102 and readout resonator 1105; and to an output capacitor 1120 with an active node at one end.

Charge qubits of the sort just described are simply gated Josephson junctions, and they are susceptible to charge noise from fluctuations in carrier density on the Josephson junction 1102. Adding a shunting capacitor 1104 modifies the capacitance-inductance ratio of the Josephson junction 1102, producing a more harmonic (but less charge-sensitive) transmon qubit. Alternatively, and with reference to FIG. 12, incorporating a large inductor 1202, realized as a series of approximately 100 Josephson junctions connected in series, results in a fluxonium qubit 1203 implementing an anharmonic oscillator (and thus a qubit) in the magnetic flux of the circuit. The fluxonium qubit 1203 may be tuned with an external flux Φₑₓₜ 1204 to reduce noise sensitivity and boost coherence times substantially, in some cases reaching timescales of milliseconds. A fluxonium qubit may also be augmented with a shunting capacitor 1104 in order to provide additional control over the addressable two-level subspace of the qubit.

Embodiments of the present invention enable the formation of other electronic devices as well, such as the central functional components of superconducting nanowire single-photon detectors (SNSPDs), used for sensing individual photons at wavelengths ranging from 250 nm (ultraviolet) to 10 μm (mid-infrared). Count rates achievable with SNSPDs are comparable to those of other high-sensitivity detectors, such as single-photon avalanche diodes or transition-edge sensors, while the achievable timing jitter may be orders of magnitude better (on the order of 5 ps to 20 ps).

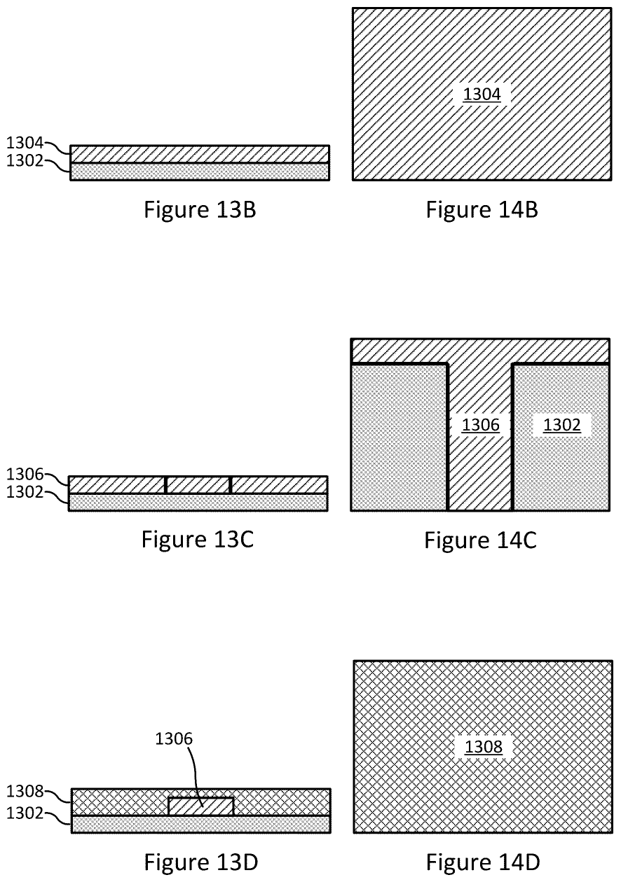

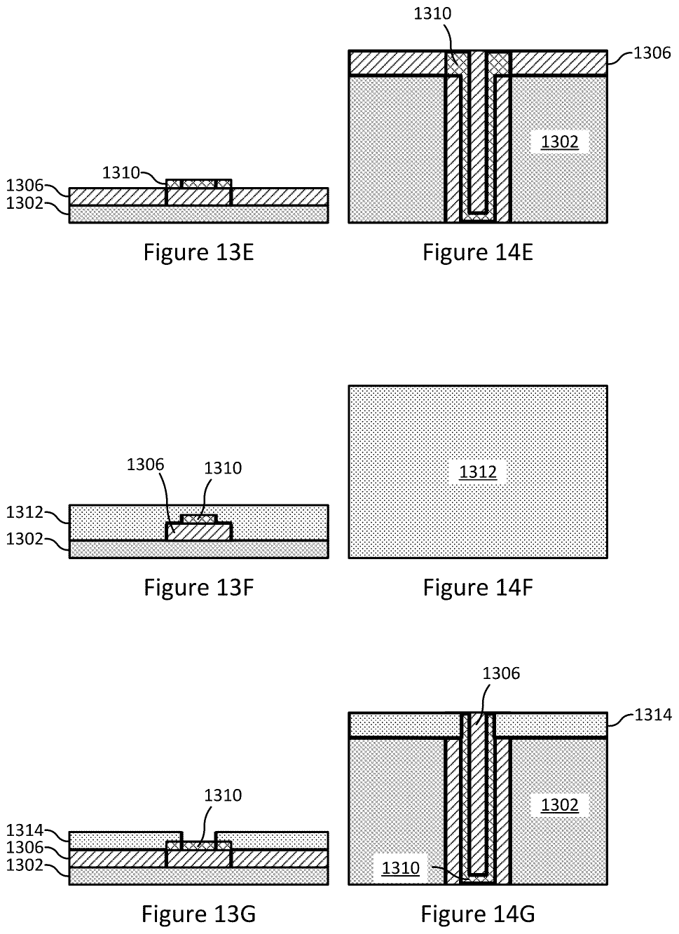

FIGS. 13A-13G and 14A-14G respectively depict cross-sectional and top-down views of the formation of a superconducting nanowire and metal contacts over a waveguide for use in SNSPDs. (Like reference numerals are used to refer to identical features of the two figures.) Beginning in FIGS. 13A and 14A with a substrate 1302, which may be a substrate in the sense described above, the device may be formed as follows:

As depicted in FIGS. 13B and 14B, a waveguide material 1304 may be deposited over the substrate 1302 using any suitable deposition technique, such as PVD by sputtering, evaporation, or molecular beam evaporation; PLD; ALD or plasma-enhanced ALD; CVD, plasma-enhanced CVD, metal-organic CVD, low-pressure CVD, or rapid thermal CVD; or any other layer deposition process or combination thereof. In some embodiments, the waveguide material 1304 may comprise a metalloid or metalloid compound, such as silicon, silicon nitride, or gallium arsenide. In other embodiments, the waveguide material 1304 may comprise a metal compound, such as aluminum nitride or lithium niobate. In still other embodiments, the waveguide material 1304 may comprise diamond, whether a single crystal or polycrystalline.

As next depicted in FIGS. 13C and 14C, the waveguide material 1304 may be patterned and etched to form a waveguide 1306 with perpendicular portions that will subsequently support metal contacts. The waveguide material 1304 may be patterned using any suitable lithography technique, such as dry lithography, immersion lithography, i-line lithography, H-line lithography, EUV lithography, or DUV lithography. The waveguide material 1304 may then be etched using any suitable dry etching method, such as reactive ion etching.

As further depicted in FIGS. 13D and 14D, a superconducting metal nitride layer 1308 may be deposited over the waveguide 1306 and the substrate 1302 by PVD employing a plasma comprising krypton and/or xenon, according to embodiments of the present invention.

Subsequently, and with reference to FIGS. 13 and 14E, the superconducting metal nitride layer 1308 may be patterned and etched to form a superconducting nanowire 1310. The superconducting metal nitride layer 1308 may be patterned using any suitable lithography technique, such as dry lithography, immersion lithography, i-line lithography, H-line lithography, EUV lithography, or DUV lithography. The superconducting metal nitride layer 1308 may then be etched using any suitable dry etching method, such as reactive ion etching.

Referring to FIGS. 13F and 14F, a metal layer 1312 may be deposited over the superconducting nanowire 1310, the waveguide 1306, and the substrate 1302 using any suitable deposition technique, such as PVD by sputtering, evaporation, or molecular beam evaporation; PLD; ALD or plasma-enhanced ALD; CVD, plasma-enhanced CVD, metal-organic CVD, low-pressure CVD, or rapid thermal CVD; or any other layer deposition process or combination thereof. The metal layer 1312 may comprise any conductive metal suitable for forming contacts, such as a common metallization element like aluminum, nickel, copper, silver, or gold, or an alloy thereof.

Referring to FIGS. 13G and 14G, the metal layer 1312 may then be patterned and etched to form metal contacts 1314 with the ends of the superconducting nanowire 1310. The metal layer 1312 may be patterned using any suitable lithography technique, such as dry lithography, immersion lithography, i-line lithography, H-line lithography, EUV lithography, or DUV lithography. The metal layer 1312 may then be etched using any suitable dry etching method, such as reactive ion etching.

The result of the steps illustrated in FIGS. 13A-13G and FIGS. 14A-14G is the superconducting nanowire 1310 integrated with the waveguide 1306 and suitable for further integration (by coupling to the metal contacts 1314) with additional devices and circuit. The superconducting nanowire 1310 thus integrated may form, as an example and in accordance with various embodiments, an SNSPD.

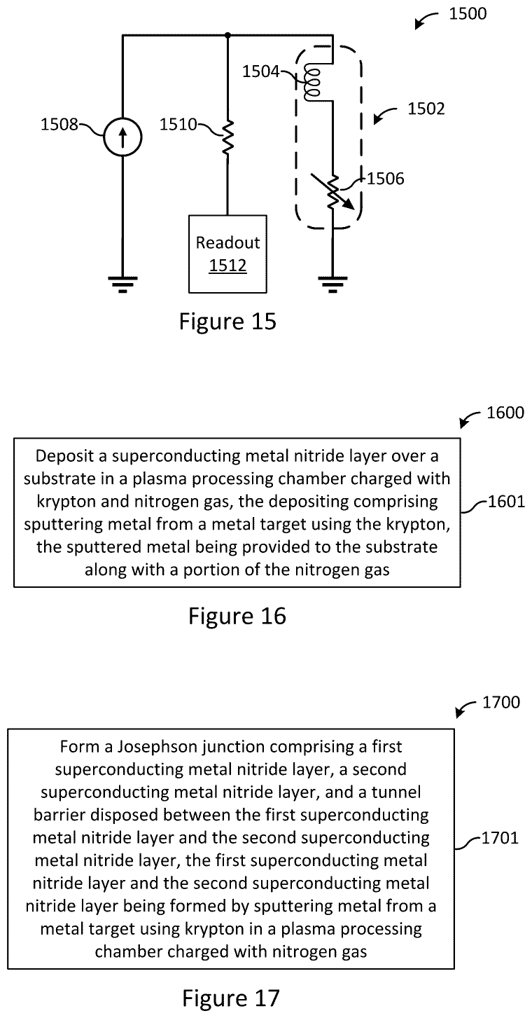

FIG. 15 provides an equivalent circuit diagram for an embodiment superconducting nanowire single-photon detector. A superconducting nanowire 1502 formed in accordance with various embodiments is cryogenically cooled into the superconducting state, with a DC power supply 1508 biasing the current flowing through the superconducting nanowire 1502 to near-critical density (i.e., such that the inductance 1504 of the superconducting nanowire 1502 corresponds to a magnetic field close to the critical value H_{c}). Absorption of a photon by the superconducting nanowire 1502 may locally heat the nanowire above T_{c} and form a resistive spot that diverts the current and further increases the carrier density, eventually leading through further heating to a non-negligible resistance 1506 in the superconducting nanowire that eventually may exceed that of a load 1510 (commonly selected to be 50Ω). Current flow from the load 1510 to a readout 1512 triggers a photodetection signal.

Given capacitively coupled PVD apparatus 100A, inductively coupled PVD apparatus 100B, or another apparatus configured to supply carrier gas 202 and nitrogen gas 204 for ignition of a plasma 132 disposed between a metal target 112 and a substrate 106 (as illustrated in FIG. 2B), embodiments of the present invention enable several methods of forming devices. These methods have been described above with reference to the respective figures and may be summarized (according to embodiments) in the flow charts of FIGS. 16-18.

FIG. 16 provides a flow chart 1600 for a method of forming a superconducting device, in which a superconducting metal nitride layer is deposited over a substrate in a plasma processing chamber charged with krypton and nitrogen gas (as illustrated in FIGS. 1A/1B and 2A/2B; see box 1601 of FIG. 16). In this method, the depositing is accomplished at least in part by sputtering metal from a metal target using the krypton in the ignited plasma, with the sputtered metal being provided to the substrate along with a portion of the nitrogen gas present in the plasma processing chamber. In some embodiments, the superconducting metal nitride layer may be between 2 nm and 15 nm in thickness. In other embodiments, the superconducting metal nitride layer may be between 15 nm and 50 nm in thickness. In still other embodiments, the superconducting metal nitride layer may be between 50 nm and 250 nm in thickness.

FIG. 17 provides a flow chart for a method. In this method (see box 1701 of FIG. 17), a Josephson junction is formed by a combination of planar processes and damascene trench-filling as illustrated in FIGS. 9A-9I and 10A-10I; in particular, a first superconducting metal nitride layer and a second superconducting metal nitride layer are formed by sputtering metal from a metal target using krypton in a plasma processing chamber charged with nitrogen gas. (The plasma processing chamber may be of the same type depicted in either of FIGS. 1A and 1B.) In some embodiments, the superconducting metal nitride layer may be between 50 nm and 250 nm in thickness.

A tunnel barrier is disposed between the superconducting metal nitride layers; FIGS. 9 and 10 depict formation and patterning of the tunnel barrier after formation of the first superconducting metal nitride layer and before formation of the second superconducting metal nitride layer, in accordance with an embodiment. Other embodiments may instead dispose the tunnel barrier between the superconducting metal nitride layers subsequent to their formation, through the use of shadow evaporation or other suitable techniques. In some embodiments, the tunnel barrier may be between 1 nm and 15 nm in thickness.

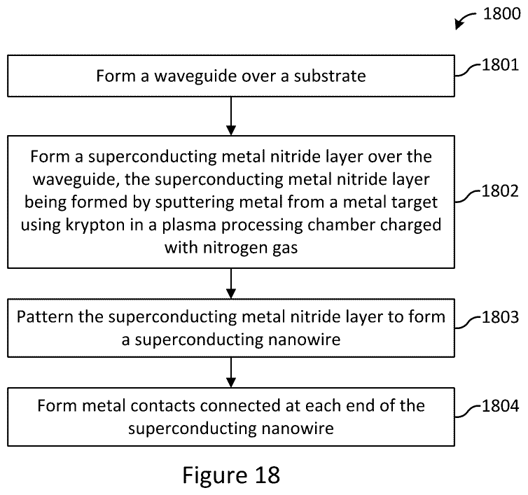

FIG. 18 provides a flow chart 1800, also for a method. In the first step of this method (see box 1801 of FIG. 18), a waveguide is formed over a substrate as illustrated in FIGS. 13A-13C and 14A-14C. (The waveguide may comprise, in various embodiments, silicon, silicon nitride, gallium arsenide, aluminum nitride, lithium niobate, or diamond.) The waveguide may be formed as linear feature in some embodiments. In other embodiments, the waveguide may be “T”-shaped (as depicted in FIGS. 13B/13C and 14B/14C), or a crosshair, or otherwise patterned such that additional features to be layered over it will be closer together relative to the surface of the substrate.

In the second step of this method (see box 1802 of FIG. 18), a superconducting metal nitride layer is formed over the waveguide by sputtering metal from a metal target using krypton in a plasma processing chamber charged with nitrogen gas, as illustrated in FIGS. 13D and 14D. (The plasma processing chamber may be of the same type depicted in either of FIGS. 1A and 1B.) In some embodiments, the superconducting metal nitride layer may be between 2 nm and 15 nm in thickness.

In the third step of this method (see box 1803 of FIG. 18), the superconducting metal nitride layer is patterned to form a superconducting nanowire, as depicted in FIGS. 13E and 14E. In some embodiments, and as illustrated in FIGS. 13E/13G and 14E/14G the superconducting nanowire may be a high-aspect ratio feature with a total length between 1 μm and 5 μm, a width between 100 nm and 250 nm, and a thickness between 2 nm and 10 nm. In other embodiments, the superconducting nanowire may be patterned as a dense meander covering an area comparable to the spot size of an optical fiber, between 25 μm² and 100 μm².

In the fourth step of this method (see box 1804 of FIG. 18), metal contacts are formed and connected at each end of the superconducting nanowire. In some embodiments, and as illustrated in FIGS. 13F/13G and 14F/14G, the contacts may be formed by layering and patterning metal over perpendicular portions of the waveguide 1306 and the ends of the superconducting nanowire 1310. In other embodiments, such as those in which the waveguide may be linear, a thicker metallization akin to filling a via may be used. Whatever the contact geometry, the complete device may then be incorporated, as an example and in accordance with certain embodiments, into a SNSPD (in some embodiments having an equivalent circuit such as that of FIG. 15).

Example embodiments of the invention are described below. Other embodiments can also be understood from the entirety of the specification as well as the claims filed herein.

Example 1. A method of forming a superconducting device includes depositing a superconducting metal nitride layer over a substrate in a plasma processing chamber charged with a first inert gas including nitrogen gas and a different second inert gas. The depositing includes sputtering metal from a metal target using the second inert gas, the sputtered metal being provided to the substrate along with a portion of the nitrogen gas.

Example 2. The method of example 1, further including establishing a pressure of gases in the plasma processing chamber between 0.25 and 30 mtorr, with a percent pressure of nitrogen gas between 30% and 70%.

Example 3. The method of one of examples 1 or 2, where a stoichiometry of the superconducting metal nitride layer includes NbNₓ with x between 0.75 and 1.0.

Example 4. The method of one of examples 1 to 3, where the metal target includes niobium, aluminum, titanium, or tantalum.

Example 5. The method of one of examples 1 to 4, where the second inert gas includes krypton or xenon.

Example 6. The method of one of examples 1 to 5, where the depositing includes: charging the plasma processing chamber with nitrogen gas and the second inert gas; igniting a plasma in the plasma processing chamber; directing the plasma toward the metal target disposed within the plasma processing chamber in order to sputter atoms of the metal target.

Example 7. The method of one of examples 1 to 6, further including holding the substrate in a temperature range between 15° C. and 300° C. while the sputtered metal is deposited.

Example 8. A method includes forming a Josephson junction including a first superconducting metal nitride layer, a second superconducting metal nitride layer, and a tunnel barrier disposed between the first superconducting metal nitride layer and the second superconducting metal nitride layer, the first superconducting metal nitride layer and the second superconducting metal nitride layer being formed by sputtering metal from a metal target using krypton in a plasma processing chamber charged with nitrogen gas.

Example 9. The method of example 8, further including establishing a pressure of gases in the plasma processing chamber between 0.25 and 30 mtorr, with a percent pressure of nitrogen gas between 30% and 70%.

Example 10. The method of one of examples 8 or 9, where the first superconducting metal nitride layer and the second superconducting metal nitride layer include NbNₓ with x between 0.75 and 1.0.

Example 11. The method of one of examples 8 to 10, where the first superconducting metal nitride layer and the second superconducting metal nitride layer include niobium.

Example 12. The method of one of examples 8 to 11, where the first superconducting metal nitride layer and the second superconducting metal nitride layer include aluminum, titanium, or tantalum.

Example 13. The method of one of examples 8 to 12, where the Josephson junction is part of a transmon qubit or a fluxonium qubit.

Example 14. A method includes forming a waveguide over a substrate; forming a superconducting metal nitride layer over the waveguide, the superconducting metal nitride layer being formed by sputtering metal from a metal target using krypton in a plasma processing chamber charged with nitrogen gas; patterning the superconducting metal nitride layer to form a superconducting nanowire; and forming metal contacts connected at each end of the superconducting nanowire.

Example 15. The method of example 14, where the waveguide includes silicon, silicon nitride, gallium arsenide, aluminum nitride, lithium niobate, or diamond.

Example 16. The method of one of examples 14 or 15, further including establishing a pressure of gases in the plasma processing chamber between 0.25 and 30 mtorr, with a percent pressure of nitrogen gas between 30% and 70%.

Example 17. The method of one of examples 14 to 16, where the superconducting nanowire includes NbNₓ with x between 0.75 and 1.0.

Example 18. The method of one of examples 14 to 17, where the superconducting nanowire includes a transition metal.

Example 19. The method of one of examples 14 to 18, where the superconducting nanowire includes niobium, aluminum, titanium, or tantalum.

Example 20. The method of one of examples 14 to 19, where the superconducting nanowire is part of a superconducting nanowire single-photon detector.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of forming a superconducting device, the method comprising:
depositing a superconducting metal nitride layer over a substrate in a plasma processing chamber charged with a first inert gas comprising nitrogen gas and a different second inert gas, the depositing comprising sputtering metal from a metal target using the second inert gas, the sputtered metal being provided to the substrate along with a portion of the nitrogen gas.

2. The method of claim 1, further comprising establishing a pressure of gases in the plasma processing chamber between 0.25 and 30 mtorr, with a percent pressure of nitrogen gas between 30% and 70%.

3. The method of claim 2, wherein a stoichiometry of the superconducting metal nitride layer comprises NbNₓ with x between 0.75 and 1.0.

4. The method of claim 1, wherein the metal target comprises niobium, aluminum, titanium, or tantalum.

5. The method of claim 1, wherein the second inert gas comprises krypton or xenon.

6. The method of claim 5, wherein the depositing comprises:
charging the plasma processing chamber with nitrogen gas and the second inert gas;
igniting a plasma in the plasma processing chamber;
directing the plasma toward the metal target disposed within the plasma processing chamber in order to sputter atoms of the metal target.

7. The method of claim 6, further comprising holding the substrate in a temperature range between 15° C. and 300° C. while the sputtered metal is deposited.

8. A method comprising:
forming a Josephson junction comprising a first superconducting metal nitride layer, a second superconducting metal nitride layer, and a tunnel barrier disposed between the first superconducting metal nitride layer and the second superconducting metal nitride layer, the first superconducting metal nitride layer and the second superconducting metal nitride layer being formed by sputtering metal from a metal target using krypton in a plasma processing chamber charged with nitrogen gas.

9. The method of claim 8, further comprising establishing a pressure of gases in the plasma processing chamber between 0.25 and 30 mtorr, with a percent pressure of nitrogen gas between 30% and 70%.

10. The method of claim 8, wherein the first superconducting metal nitride layer and the second superconducting metal nitride layer comprise NbNₓ with x between 0.75 and 1.0.

11. The method of claim 8, wherein the first superconducting metal nitride layer and the second superconducting metal nitride layer comprise niobium.

12. The method of claim 8, wherein the first superconducting metal nitride layer and the second superconducting metal nitride layer comprise aluminum, titanium, or tantalum.

13. The method of claim 8, wherein the Josephson junction is part of a transmon qubit or a fluxonium qubit.

14. A method comprising:
forming a waveguide over a substrate;
forming a superconducting metal nitride layer over the waveguide, the superconducting metal nitride layer being formed by sputtering metal from a metal target using krypton in a plasma processing chamber charged with nitrogen gas;
patterning the superconducting metal nitride layer to form a superconducting nanowire; and
forming metal contacts connected at each end of the superconducting nanowire.

15. The method of claim 14, wherein the waveguide comprises silicon, silicon nitride, gallium arsenide, aluminum nitride, lithium niobate, or diamond.

16. The method of claim 14, further comprising establishing a pressure of gases in the plasma processing chamber between 0.25 and 30 mtorr, with a percent pressure of nitrogen gas between 30% and 70%.

17. The method of claim 16, wherein the superconducting nanowire comprises NbNₓ with x between 0.75 and 1.0.

18. The method of claim 14, wherein the superconducting nanowire comprises a transition metal.

19. The method of claim 14, wherein the superconducting nanowire comprises niobium, aluminum, titanium, or tantalum.

20. The method of claim 14, wherein the superconducting nanowire is part of a superconducting nanowire single-photon detector.
